(19) United States
(12) Patent Application Publication
(10) Pub. No.: US 2018/0019298 A1
(43) Pub. Date: Jan. 18, 2018

(54) METHOD FOR FORMING PATTERNED TANTALUM NITRIDE (TaN) RESISTORS ON DIELECTRIC MATERIAL PASSIVATION LAYERS

(71) Applicant: Raytheon Company, Waltham, MA (US)

(72) Inventors: Kiuchul Hwang, Amherst, NH (US); Robert T. Soter, Spencer, MA (US); Bruce Leblanc, Manchester, NH (US); Adrian D. Williams, Methuen, MA (US)

(73) Assignee: Raytheon Company, Waltham, MA (US)

(21) Appl. No.: 15/212,709

(22) Filed: Jul. 18, 2016

(51) Int. Cl. H01L 49/02; H01L 23/31; H01L 23/29; H01L 21/8234; H01L 21/3213; H01L 21/3205; H01L 21/027; H01L 27/06; H01L 21/02

(52) U.S. Cl. CPC H01L 28/24; H01L 27/0629; H01L 23/3171; H01L 23/291; H01L 21/0217; H01L 21/32139; H01L 21/32051; H01L 21/0273; H01L 21/8234

(57) ABSTRACT

A structure having: a substrate; a passivation layer disposed over a surface of substrate; an etch stop layer disposed on the passivation layer; resistor comprising tantalum nitride, disposed on the etch stop layer. The etch stop layer has an etch rate at least 100 times slower than an etch rate of the tantalum nitride to a predetermined etchant.

### TECHNICAL FIELD

This disclosure relates generally to methods for forming tantalum nitride (TaN) resistors and more particularly to methods for forming tantalum nitride (TaN) resistors on dielectric material passivation layers.

### BACKGROUND

As is known in the art, tantalum nitride (TaN) thin films are used in many applications such as for example to form resistors, which are a critical passive component, on RFICs (Radio Frequency Integrated Circuits) and MMICs (Monolithic Microwave Integrated Circuits). A TaN resistive film is usually deposited on top of a dielectric passivation layer, such as silicon nitride or silicon dioxide, for example, to protect active transistors such as FETs (Field Effect Transistors) and BJTs (Bipolar Junction Transistors) and then patterned into the resistor using a masking-etching process. More particularly, current process to form resistors to make integrated circuits typically starts with deposition of TaN across on top of the dielectric passivation layer, such as a silicon nitride or silicon dioxide film disposed on top of substrate wafer. Then a certain area to form a resistor is covered with photoresist mask to protect the resistor area during a dry etch process that removes all the unmasked TaN resistive film on top of the passivation dielectric film. The dry etch process is supposed to remove only the portion of the TaN film exposed by the mask, and should not etch off the passivation dielectric film underneath the exposed TaN; however, the etch rate selectivity between TaN and the dielectric passivation layer or film under the TaN is in a range of from 1 to 1 to 10 to 1 depending on the dry etch gas chemistry. Therefore, if the thickness of TaN is 400 to 500 nm, and the thickness of a silicon nitride passivation layer underneath the TaN is 40 to 50 nm, for example, the dry etch process may damage the passivation film. Thus, with the mask formed over the portion of the TaN resistive film where the resistor is to be formed, the unmasked portions of the TaN are etched away using a dry etch process applied for a period of time calculated from predetermined etch rate of TaN resistive film and the thickness of the TaN resistive film. The practical application of such a timed etch process leads to undesired etching of the underlying silicon nitride film due to poor etch selectivity between the TaN film and the silicon nitride film using typical halogen-based pasma or wet chemistries.

### SUMMARY

In accordance with the present disclosure, a structure is provided having: a substrate; a passivation layer disposed over a surface of substrate; an etch stop layer disposed on the passivation layer; resistor comprising tantalum nitride, disposed on the etch stop layer. The etch stop layer has an etch rate at least 100 times slower than the etch rate of the tantalum nitride to a predetermined etchant.

In one embodiment, the passivation layer is a nitride and the predetermined etchant is a non-nitrogen compound etchant.

In one embodiment, the passivation layer is silicon nitride;

In one embodiment the passivation layer is silicon dioxide.

In one embodiment, the etchant is a halogen.

In one embodiment, the etch stop layer is aluminum oxide.

In one embodiment, a method is provided, comprising: forming a dielectric passivation layer over a surface of a substrate; forming an etch stop layer on the dielectric passivation layer; and forming a tantalum nitride layer on the etch stop layer. The etch stop layer has an etch rate at least 100 times slower than an etch rate of the tantalum nitride layer to a predetermined etchant. The method includes: masking a selected portion of a surface of the tantalum nitride layer while exposing adjacent portions of the selected portion of the surface of the tantalum nitride layer; and subjecting both the masked selected portion of the tantalum nitride layer and the exposed adjacent portions of the tantalum nitride layer to the predetermined etchant to selectively remove the exposed adjacent portions of the tantalum nitride layer while leaving the masked selected portion of the tantalum nitride layer.

Thus, in accordance with the disclosure, a thin dielectric film such as an aluminum oxide film is introduced between the TaN resistor film and passivation film as an etch stop layer. The inventors have recognized that the etch rate selectivity between TaN resistive film and aluminum oxide dielectric film is almost infinite when using a chlorine and/or fluorine gas dry etch process. Therefore, the aluminum oxide film can be used as an excellent etch stop layer, so the dry etch process etches off TaN resistive film, then stops at aluminum oxide layer. The disclosure thus solves a problem of poor etch selectivity between a TaN resistive film and passivation layer by introducing a thin highly etch rate selective dielectric film. In this way, then thin dielectric passivation film underneath TaN resistive film is not damaged or altered during the removal of TaN resistive film thereby significantly improving chip yield.

The inventors have also recognized significant etch rate difference between tantalum nitride and aluminum oxide. More particularly, the inventors have recognized the following: Equations (1), (2) and (3) below describe products resulting from the dry etch processing of tantalum nitride resistive film (TaN), silicon nitride film (SiN), and aluminum oxide film (Al₂O₃), respectively, with chlorine based gas. The volatility of the products of TaCl and SiCl (equations (1) and (2)) are much higher than that of AlCl, the product of equation (3), Therefore the selective etching of TaN resistive film on top of a SiN film using chlorine based dry etch process is very poor. However aluminum chloride (AlCl) formed by dry etch process using chlorine based gas has very low volatility, so the high selectivity between TaN, SiN, and Al2O3 using a chlorine based dry etch process makes the Aluminum oxide film to be an excellent etch stop layer.

TaN+Cl₂=TaCl+N₂ (1)

SiN+Cl₂=SiCl+N₂ (2)

Al₂O₃+Cl₂=AlCl+O₂ (3)

Further, a similar dry etch reaction occurs when fluorine based gas, for example SF6, is used to etch TaN, SiN, and Al2O3 films.

TaN+SF₆=TaF+N₂+S (3)

SiN+SF₆=SiF+N₂+S (4)

Al₂O₃+SF₆+=AlF+O2+S (5)

More particularly, the volatility of Tantalum fluoride (TaF) and Silicon fluoride (SiF) is much higher than Aluminum fluoride (AlF), therefore the high selectivity between TaN, SiN, and Al₂O₃ under fluorine based dry etch process makes the alumninum oxide film to be an excellent etch stop layer.

Thus, time based day etch process using chlorine based gas or fluorine based gas to selectively etch off a tantalum nitride film on top of silicon nitride film increases the risk to over etching that may damage underlying portions of the silicon nitride dielectric passivation film or under etching that may leave TaN resistive film on a certain undesired areas.

The details of one or more embodiments of the disclosure are set forth in the accompanying drawings and the description below. Other features, objects, and advantages to of the disclosure will be apparent from the description and drawings, and from the claims.

### DESCRIPTION OF DRAWINGS

FIGS. 1 through 7 is a series of diagrammatic cross sectional sketches at various stages in fabricating an active device electrically connected to a resistor according to the disclosure.

Like reference symbols in the various drawings indicate like elements.

### DETAILED DESCRIPTION

Referring now to FIG. 1, a semiconductor substrate 10 is provided. Here, substrate 10 may be, for example, GaAs, AlGaAs, AlAs, InAlAs, InGaAs, InP, SiC, GaN, AlGaN, InAlN, InGaN or Si. Next, an active device 12, here for example, a Field Effect Transistor (FET) is formed having a source contact, a gate contact and a drain contact; it should be understood that other active devices such as, for example, BJTs (Bipolar Junction Transistors) may be formed having an emitter contact, a base contact and a collector contact, not shown, using any conventional process.

Next, referring to FIG. 1, a dielectric passivation layer, 14, here for example, silicon nitride is deposited by the mixture of two gases, silane (SiH₄) and ammonia (NH₃) with PECVD (Plasma Enhanced Chemical Vapor Deposition) for passivation on the FET (Field Effect Transistor) 12, as shown. Here, for example, the passivation layer 14 has a thickness in a range of 20 nm to 300 nm depending on the application because, for example, this passivation layer 14 could be also used as a dielectric for a capacitor, not shown, in an integrated circuit, for example.

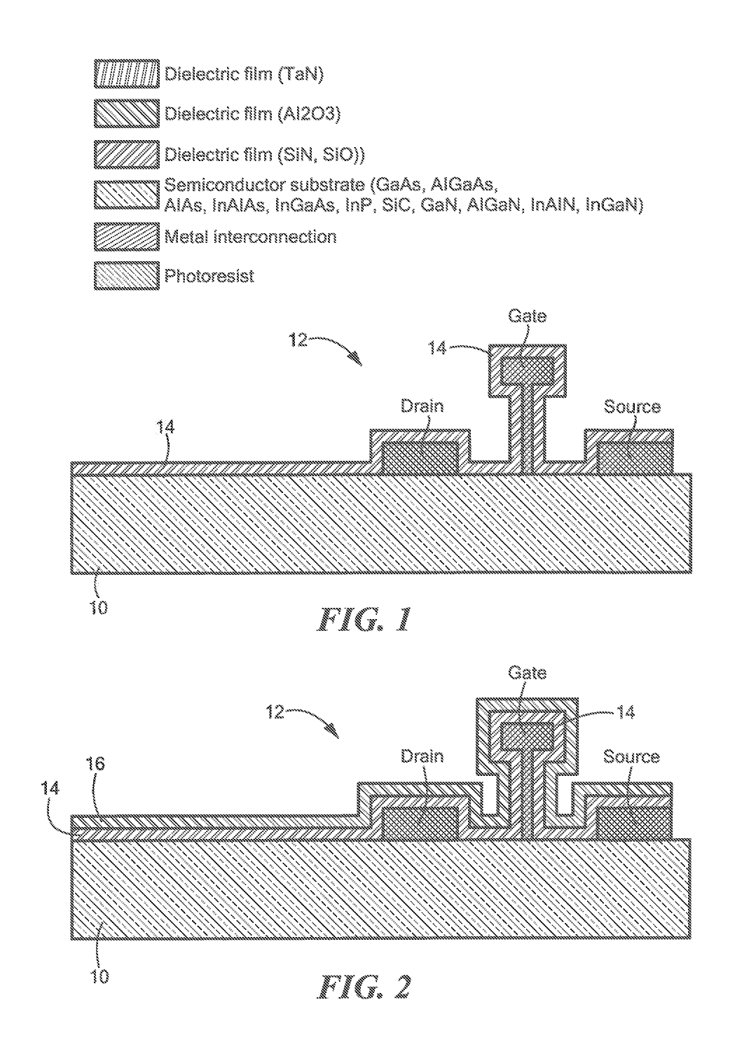

Next, referring to FIG. 2, a second dielectric film, 16, here for example, Aluminum Oxide (Al₂O₃) is deposited over the passivation layer, 14 by, here for example an ALD (Atomic Layer Deposition) thin film technology, here for example, with a non-pyrophoric, oxygen-five, halogen-free Tris (diethylamino) aluminum (TDEAA) precursor. Here the second dielectric film 16 has, for example, a thickness in a range of 2 to 5 nm, for example. As will be described, the second dielectric film 16 will serve as an etch stop layer.

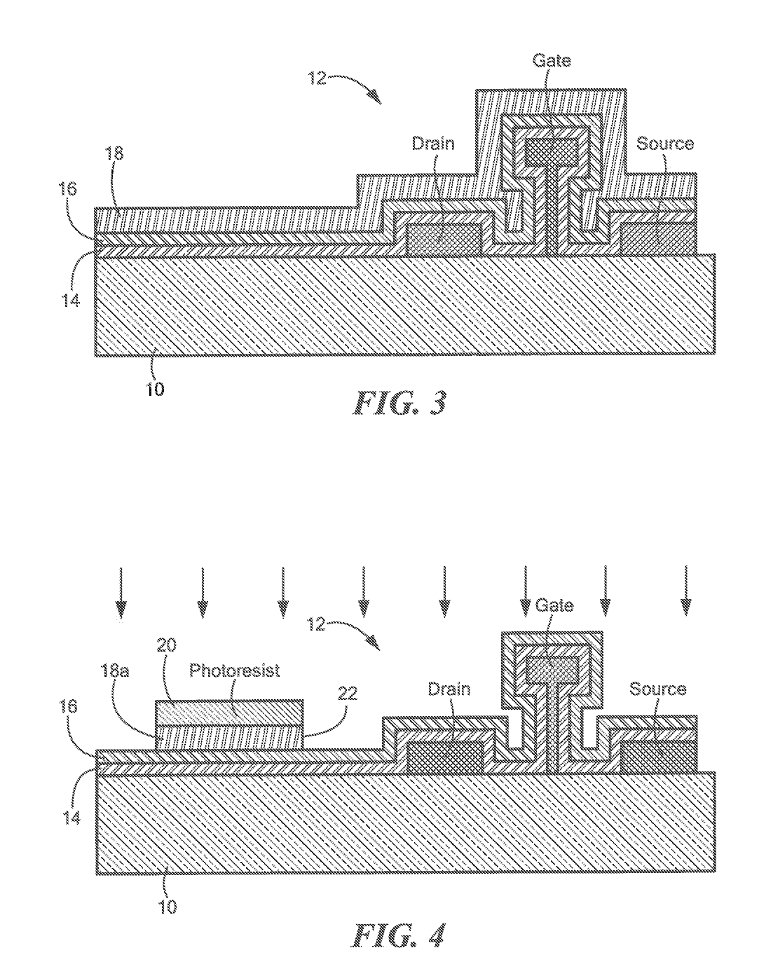

Next, referring to FIG. 3, a third film 18, here of an electrically resistive material, here for example, tantalum nitride (TaN) is deposited over the second dielectric layer 16, by flowing nitrogen gas during sputtering of a Tantalum target, not shown. Here, for example, the third film 18 has a thickness in a range of 20 nm to 10 nm. Here, for example, the sputtered TaN has an electrical resistivity in the range of 20 Ω/square to 80 Ω/square.

Next, referring to FIG. 4, a photoresist mask 20 is formed, using conventional photolithographic-etching techniques, over the portion of the third film 18 where a resistor 22 having a predetermined electrical resistance. For a predetermined composition of TaN material 18, the electrical resistance of resistor 22 is a function of the physical dimensions of the TaN resistive film 18; e.g., the length, width and thickness of the film 18.

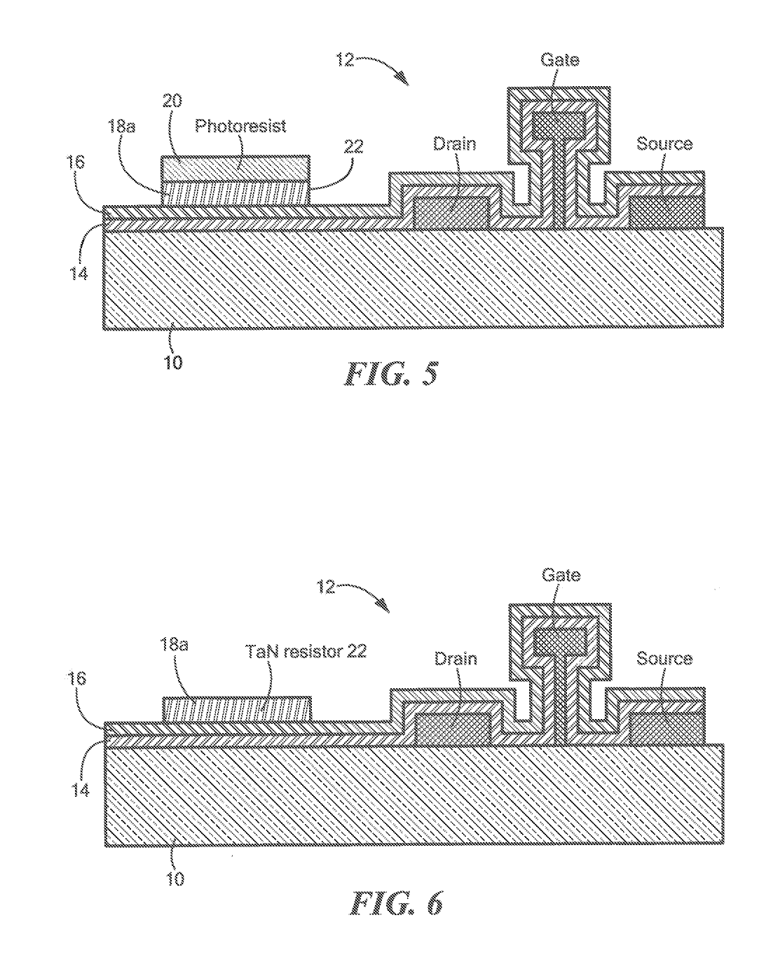

Next, referring to FIG. 5, the upper surface of the structure shown in FIG. 4 is subject to a dry etch, indicated by the arrows in FIG. 4, here, for example, non-nitrogen containing etch; here, for example a halogen based gas such as, for example, fluorine (F) based SF₆, chorine (Cl₂) based BCl₃, or a combination of fluorine (F), chorine (Cl₂) such as, for example trichlorofluometane (CCl₃F₄), carbon tetrafluoride (CF₄), to remove all portions of the resistive film 18 (e.g., the exposed portions of the TaN resistive material) exposed by the mask 20. It is noted that the etch rate of the second dielectric film, 16, (for example, the aluminum oxide (Al₂O₃)) is almost zero compared to the etch rate of the resistive film 18 (e.g., the exposed portions of the TaN resistive material) to the dry etch used to etch the resistive film 18. Thus, the etch rate of the second dielectric film, 16, is at least 100 times less than the etch rate of the resistive film 18 to the etchant used to etch the TaN resistive film 18. Thus, as noted above, the second film, 16, (for example, the aluminum oxide (Al₂O₃)) acts as an etch stop layer and the dry etching may be terminated in a highly controllable manner so as not to etch into the first dielectric passivation film 14.

Next, referring to FIG. 6, the mask 20 is stripped away leaving with the remaining portion of the third film 18a providing a TaN resistor 22.

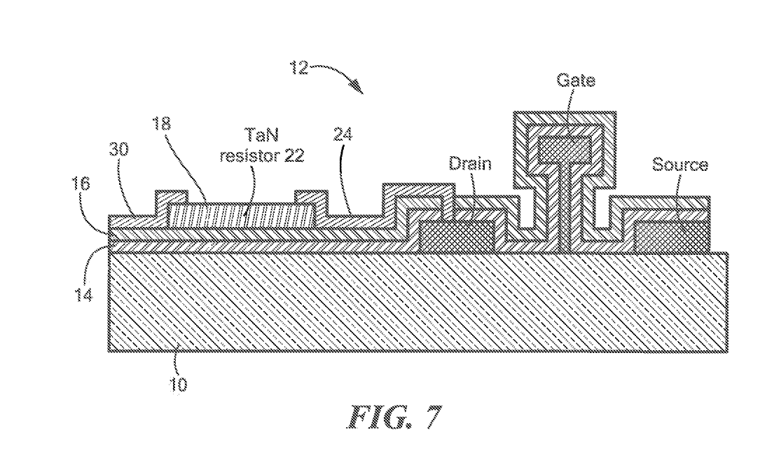

Next, referring to FIG. 7, a metal interconnect 24 is formed between the active device 12 and the TaN resistor 22 using any conventional process thereby producing an active device 12 electrically connected to a TaN resistor 22. It is noted that while here one electrode 32 of the resistor 22 is connected to the drain of the device 12, the other electrode 30 is adapted for coupling to another device, such as a capacitor, not shown, or a voltage supply, not shown.

Thus, in accordance with the disclosure, a thin dielectric film such as aluminum oxide film is introduced between the TaN resistor film and passivation film. The aluminum oxide film is an excellent etch stop layer, so the dry etch process etches off TaN resistive film, then stops at aluminum oxide layer. The disclosure thus solves a problem with poor etch selectivity between a TaN film and a passivation layer by introducing a thin highly etch rate selective dielectric layer. In this way, then thin dielectric passivation film, such as silicon nitride and silicon dioxide, underneath TaN resistive film is not damaged or altered during the removal of TaN film thereby improving chip yield.

A number of embodiments of the disclosure have been described. Nevertheless, it will be understood that various modifications may be made without departing from the spirit and scope of the disclosure. Accordingly, other embodiments are within the scope of the following claims.

1. A structure, comprising:
a substrate;
a passivation layer disposed over a surface of the substrate.
an etch stop layer disposed over the passivation layer;
a resistor comprising tantalum nitride disposed over the etch stop layer; and
wherein etch stop layer has an etch rate at least 100 times slower than an etch rate of the tantalum nitride to a predetermined etchant.

2. The structure recited in claim 1 wherein the etch stop layer is a non-nitrogen layer.

3. The structure recited in claim 1 wherein the predetermined etchant is a non-nitrogen etchant.

4. The structure recited in claim 2 wherein the predetermined etchant is a halogen based etchant.

5. The structure recited in claim 1 wherein the etch stop layer is Al₂O₃.

6. The structure recited in claim 1 wherein the passivation layer is a nitride.

7. The structure recited in claim 1 including a passivation layer is an oxide.

8. The structure recited in claim 6 wherein the passivation layer is silicon nitride.

9. A structure, comprising:
a substrate;
a passivation layer disposed over a surface of the substrate.
an etch stop layer disposed over the passivation layer;
a resistor comprising tantalum nitride disposed over the etch stop layer.

10. A method, comprising:
providing a semiconductor substrate;
forming a dielectric passivation layer on the substrate;
forming an etch stop on the passivation dielectric layer
depositing an electrically resistive material comprising tantalum nitride (TaN) on the etch stop layer;
forming mask over a selected portion of the electrically resistive material, the mask exposing unselected portions of the electrically resistive material;
exposing the mask and the unselected portions of the electrically resistive material to an etchant, to etch away the unselected portions of the electrically resistive material while remaining unetched the selected portion of the electrically resistive material disposed under the mask, the etching stopping at the etch stop layer; and,
removing the mask.

11. The method structure recited in claim 10 wherein the etch stop layer is a non-nitrogen layer.

12. The method recited in claim 10 wherein the predetermined etchant is a non-nitrogen etchant.

13. The method recited in claim 11 wherein the predetermined etchant is a halogen based etchant.

14. The method recited in claim 10 wherein the etch stop layer is Al₂O₃.

15. The method recited in claim 10 wherein the passivation layer is a nitride.

16. The method recited in claim 10 including a passivation layer is an oxide.

17. The method recited in claim 15 wherein the passivation layer is silicon nitride.
